(19) United States
(12) Patent Application Publication
(10) Pub. No.: US 2006/0041819 A1
(43) Pub. Date: Feb. 23, 2006

(54) Data decoding method and the system thereof

(75) Inventors: Yung-Chi Yang, Hsinchu (TW); Chang-Po Ma, Hsinchu (TW); Ming-Chang Tsai, Hsinchu (TW)

Correspondence Address: BIRCH STEWART KOLASCH & BIRCH, PO BOX 747, FALLS CHURCH, VA, 22040-0747, US

(73) Assignee: Industrial Technology Research Institute

(21) Appl. No.: 11/033,171

(22) Filed: Jan. 12, 2005

(30) Foreign Application Priority Data
Aug. 20, 2004 (TW) 93125290

(51) Int. Cl. H03M 13/00

(52) U.S. Cl. 714/758

(57) ABSTRACT

This specification discloses a data decoding method and the corresponding system. By improving the execution order of the error detection process during data decoding and using a descramble hardware processing structure, the method and the system can effectively reduce the number of times of memory access during the data decoding. Therefore, the disclosed method and system achieve the goal of reducing the clock needed for memory operations.

### BACKGROUND OF THE INVENTION

1. Field of Invention

The invention relates to a data decoding method and the system thereof. In particular, it relates to a method and system of improving the error detection and error correction process and the hardware processing structure to reduce the number of times of memory access during data decoding.

2. Related Art

In order to effectively store and properly protect data in a recording medium, the stored data are often encoded according to a specific encoding procedure. A traditional encoding process 1 is shown in FIG. 1A. In the beginning, main data are read in. An identification (ID), an identification error detection code (IED), and a copyright protection mode (CPRM) are added in front of the main data. Furthermore, an error detection code (EDC) is added into the main data. Afterwards, the main data are scrambled. The scrambled main data are added with two series of error correction code (ECC), the first series of error correction code, PI, and the second series of error correction code, PO, for the rows and columns, respectively, in order to generate a block called the error correction code block. The error correction code block is then interleaved, and inserted the SYNC data. After the modulation procedure, the main data encoding process has complete, and the modulated data are stored in a recording medium.

When one wants to use the main data in the recording medium, a corresponding decoding process has to be used. The traditional decoding process 2 is exactly opposite to the encoding process. As shown in FIG. 1B, the modulated data are read out from the recording medium. After detecting the synchronization data, they are demodulated. The demodulated data are further detected for the ID. The data are then deinterleaved. The deinterleaved error correction code block is corrected according to the PI and PO decoding. Finally, the main data is descrambled before entering the computation of the EDC. Once the computation shows that there is no error in the main data, they can be used accordingly.

The most important part in the traditional decoding process is shown in FIG. 1C. First, the demodulation module 10 reads the modulated data out from the recording medium, demodulates them, and stores the demodulated data in the memory module 11 (step S1). Afterwards, the demodulated data are read out from the memory module 11 for the first decoding module 12 to perform the first series of error correction code (PI) decoding (step S2). The decoded error positions and error magnitude are sent to the error correction module 15 to correct the errors in the data stored in the memory module 11. Once finished, the corrected data are read out again from the memory module 11 for the second decoding module 13 to perform the second series of error correction code (PO) decoding (step S3). The decoded positions and error magnitudes are also sent to the error correction module 15 to correct the errors in the data stored in the memory module 11. Finally, the descrambling and EDC computing module 14 is used to read out the corrected data from the memory module 11 to perform both descrambling and EDC computations (step S4). Once finished, the descrambled data are stored back in the memory module 11 (step S5). After the EDC computation procedure confirms that there is no error in the main data, they are allowed for the user to access (step S6).

We know from there that the conventional decoding method as in FIG. 1C requires at least six times of accesses to the memory module 11 (i.e. steps S1 to S6). This means that one has to use a memory module 11 with a higher clock rate in order to maintain a certain decoding efficiency. This in turn means a high cost to implement such a decoding system.

To solve this problem, an improved decoding method and the corresponding system are disclosed in the U.S. Pat. No. 6,470,473. The primary characteristic of this method is in the execution order of the error detection procedure during decoding. (For example, steps S1 and S2, steps S3 and S4 in the above-mentioned procedure are processed at the same time, saving two times of memory access.) In the system, many independent memory units are used to process the decoding procedures of the first and second series of error correction code. It even uses extra memory to store the demodulated data. Although this kind of system and method can reduce the number of memory access times down to four, the added memory occupies quite some space on the hardware. This inevitable increases the volume and production cost of the hardware.

Under the premise of keeping the efficiency, how to reduce the number of direct memory access times without increase the system hardware space and production cost is always a very important problem in the field.

### SUMMARY OF THE INVENTION

In view of the foregoing, the invention provides a new data decoding method and the system thereof. Its main feature is in the change of execution order in the error detection procedure. The goal of reducing memory access during data decoding is achieved using the processing structure of the system hardware. It further achieves the goals of reducing the production cost, increasing the number of error correction times, and decreasing the memory clock requirement.

The disclosed data decoding method, as shown in FIG. 2A, has the following featured means. (1) It simultaneously executes the demodulation procedure, the first-time first series of error correction code decoding procedure, and the descrambling procedure. (2) It gets the descrambled results and error positions and error magnitudes obtained from the first-time first series of error correction code decoding procedure to perform EDC computation. (3) It combines the previously computed EDC and the error positions and error magnitudes obtained from the second series of error correction code decoding procedure or the first series of error correction code decoding procedure except the first-time to re-computes the EDC. (4) The descrambled main data are not stored back to the memory; thus, the memory only keeps scrambled main data. (5) Once no error of the main data is found in the EDC computation, the scrambled main data are read from the memory for descrambling, and are provided for the user to use.

Through the data decoding procedure mentioned in the above embodiment, the number of memory access times could be reduced down to three without the consideration of error corrections.

The disclosed data decoding system, as shown in FIG. 2B, is different from the prior art in that: (1) it reduces the independent memory needed for processing the error correction code decoding; (2) it adopts several independent descrambling hardware processing structrues for descrambling; (3) it combines the error positions and error magnitudes obtained in the first series of error correction code decoding procedure and the descrambled result to perform the EDC computation; (4) it combines the previously computed EDC result and the error positions and error magnitudes obtained from the second series of error correction code decoding procedure or the error positions and error magnitudes obtained from the first series of error correction code decoding procedure except the first time to perform the EDC computation; (5) the descrambled main data are not stored back in the memory, and the memory only keeps the scrambled main data; (6) once no error of the main data is found in the EDC computation, the scrambled main data are read from the memory, and are provided for the user to use after descrambling.

The disclosed data decoding method and system can reduce much of the memory cost or the system hardware cost by saving the internal memory space.

### BRIEF DESCRIPTION OF THE DRAWINGS

The invention will become more fully understood from the detailed description given hereinbelow illustration only, and thus are not limitative of the present invention, and wherein:

FIG. 1A is a schematic flowchart of a conventional data encoding;

FIG. 1B is a schematic flowchart of a conventional data decoding;

FIG. 1C is a schematic block diagram of a conventional data decoding system;

FIG. 2A is a flowchart of the disclosed data decoding method;

FIG. 2B is a schematic block diagram of the disclosed data decoding system; and

FIG. 3 is a comparison table of the clock rate for requiring the memory module between the invention and the conventional data decoding.

### DETAILED DESCRIPTION OF THE INVENTION

We propose a new data decoding method and the system thereof. They are mainly used to solve the decoding problem for data stored in a recording medium. The data are usually added with an error detection code (EDC), added a first series of error correction code and a second series of error correction code after executed a scrambling procedure, and are modulated before being stored to the recording medium.

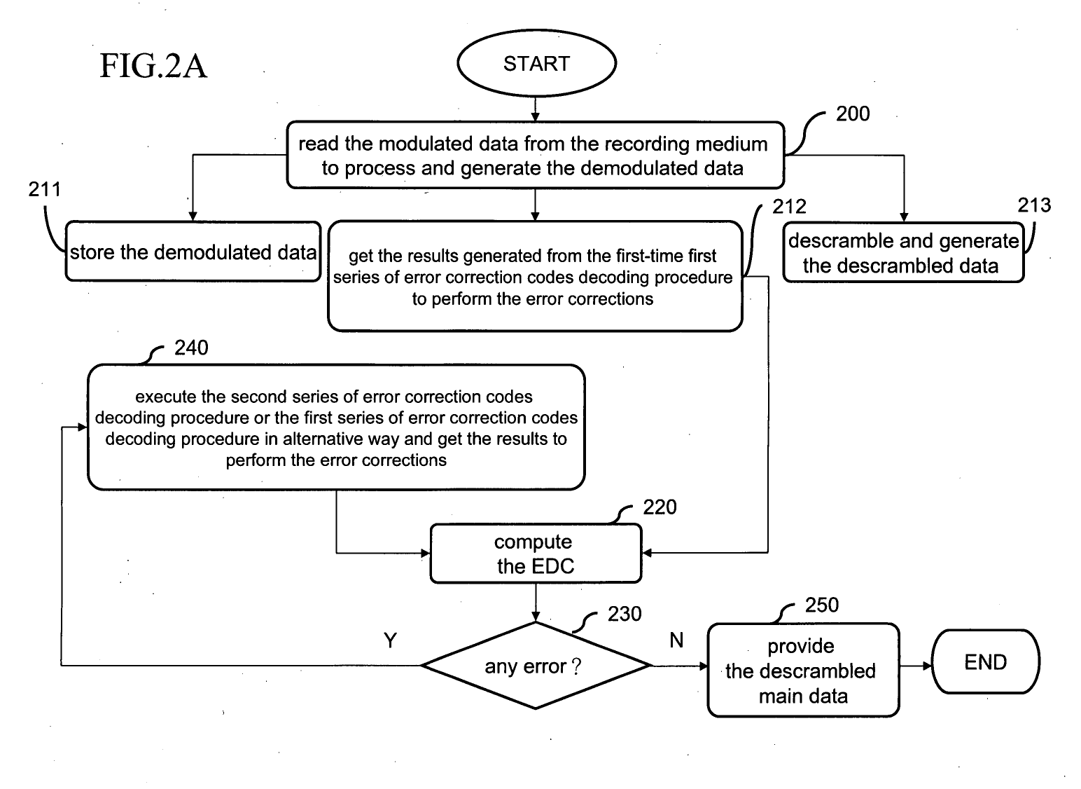

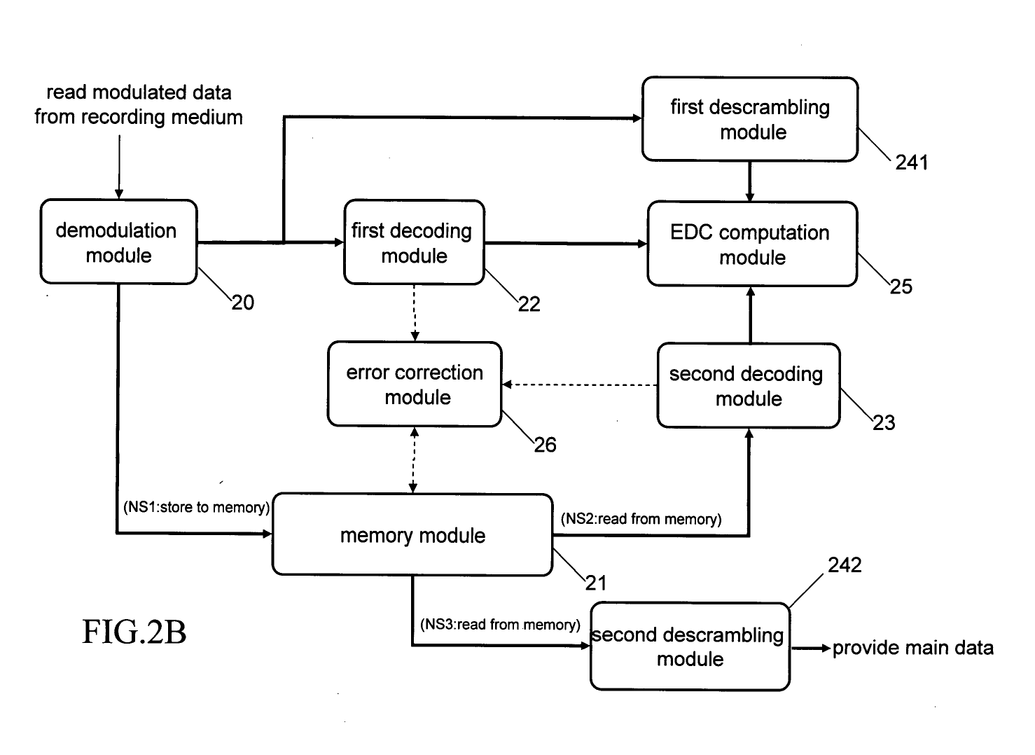

In the following, we use FIGS. 2A and 2B, the flowchart and system block diagram of the invention, respectively, to explain the details.

The modulated data are read from a recording medium for a demodulation module 20 to process and generate demodulated data (step 200). The demodulated data are simultaneously transmitted to a memory module 21 for storage (step 211), to a first decoding module 22 to perform a first-time first series of error correction code decoding procedure and using the error positions and error magnitudes obtained from the first decoding module 22 to execute error correction in the memory module 21 through the error correction module 26 (step 212), and to a first descrambling module 241 to descramble and generate descrambled data (step 213).

Afterwards, a second decoding module 23 reads out the corrected, demodulated data from the memory module 21 and performs a first-time second series of error correction code decoding. The error positions and error magnitudes obtained from the decoding are sent to the error correction module 26 to make further corrections on the demodulated data in the memory module 21 (step 240).

The error detection code computation in step 220 has two parts. (1) The error positions and error magnitudes obtained after the first-time first series of error correction code decoding are transmitted to the EDC computation module 25, and combine with the descrambled data generated by the first descrambling module 241 in step 213 to compute the result of EDC. (2) The error positions and error magnitudes obtained after the first-time second series of error correction code decoding in step 240 are transmitted to the EDC computation module 25 and combines with the EDC result computed in part (1) to re-compute it.

The EDC result computed in step 220 is used to determine whether there is any error in the main data (step 230). If no error is found in the main data, the scrambled data stored in the memory module 21 are allowed to be read out. After the descrambling of a second descrambling module 242, the main data are restored for the user to use (step 250), finishing the whole decoding procedure.

On the other hand, if we find out that there is an error in the main data in the EDC computation after the first-time first series of error correction code decoding or the first-time second series of error correction code decoding (step 230), the first series of error correction code decoding and the second series of error correction code decoding has to be performed again. Errors are corrected according to the decoding result.

The part of re-doing the first series of error correction code decoding or the second series of error correction code decoding is left for the second decoding module 23 to process (step 240). The error positions and error magnitudes generated by the first series of error correction code decoding or those of the second series of error correction code decoding are transmitted to the error correction module 26 to correct the errors. They are also sent to the EDC computation module 25 to combine with the previous EDC computation result for re-computing the EDC result until there is no error can be found in the main data in the EDC computation. (In practice, the whole decoding procedure may be abandoned if the repeated EDC computations exceed a predetermined number of times due to the consideration of efficiency.)

Therefore, the data decoding process described in the above embodiment can greatly reduce the number of direct memory module 21 access times down to at least three, i.e. as NS1, NS2, and NS3 shown in FIGS. 2A and 2B. When the data errors can be corrected using only step 212, the number of direct memory module access times can be further reduced down to two, i.e. NS1 and NS3. Thus, the needed clock rate of the memory module 21 is reduced. Due to the system hardware adjustment, the overall cost can be greatly reduced too.

Another feature of the disclosed method and system is as follows. The data finally stored in the memory module 21 after decoding are the scrambled main data. That is, the data descrambled by the first descrambling module 241 are not stored into the memory module 21. This is different from the prior art. Therefore, when a user wants to use the main data, a second descrambling module 242 has to be used to descramble the main data in the memory module 21.

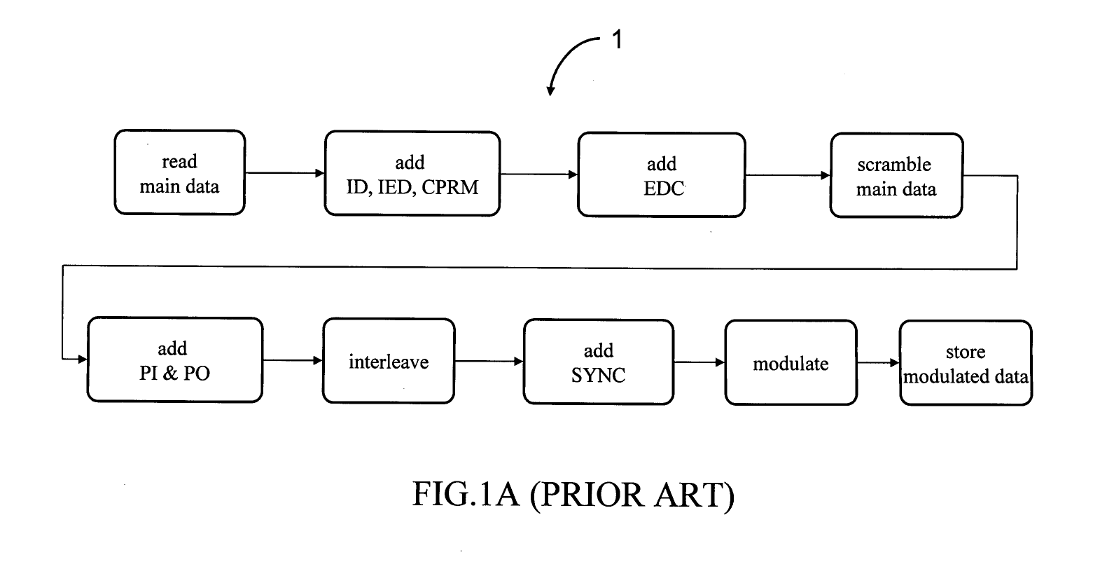

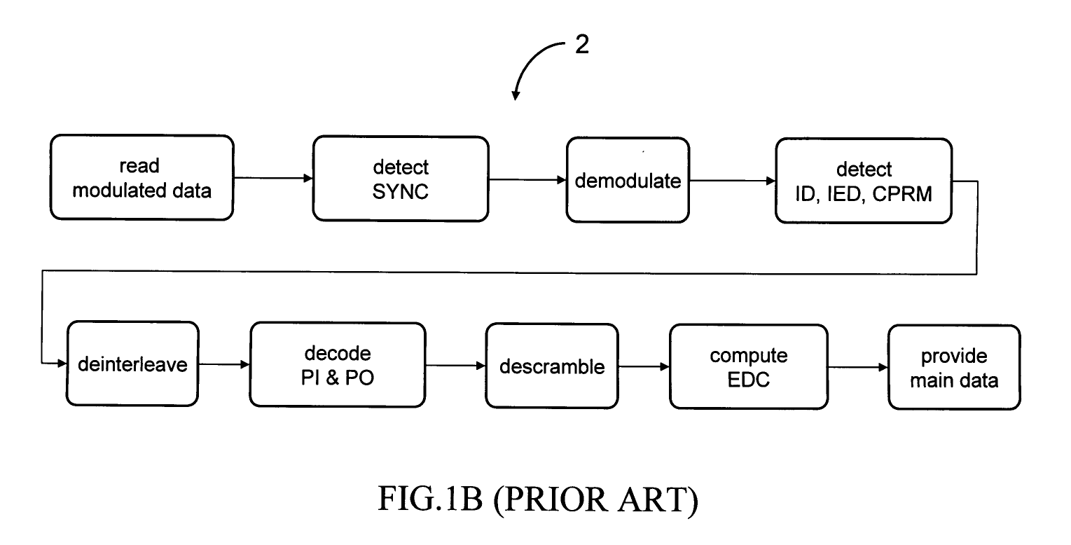

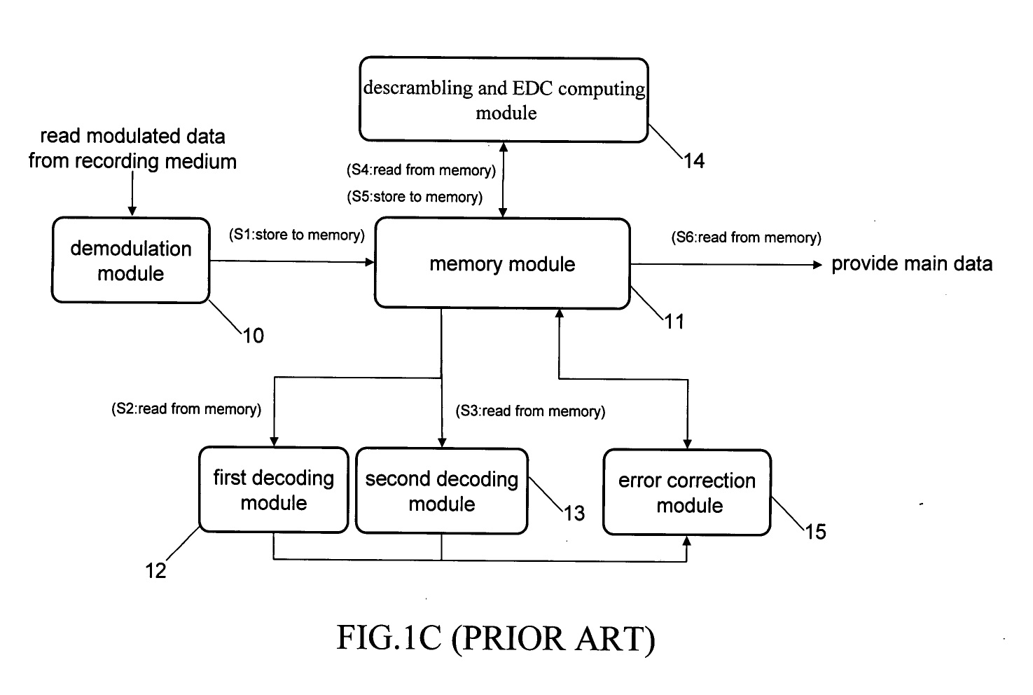

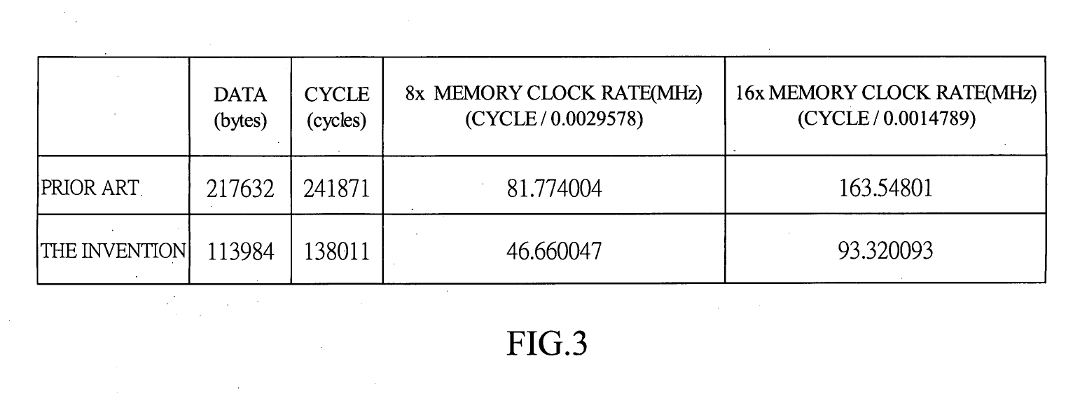

FIG. 3 shows a comparison table of the clock rate of the memory module 21 in the prior art and the invention. From the above description, one knows that the needed number of access times in the prior art (FIG. 1) is at least six (i.e. S1 to S6), whereas the invention only needs at least three (i.e. NS1 to NS3). Without considering error corrections (that is, considering the ideal situation where only one time of first series of error correction code decoding process and one time of second series of error correction code decoding process) and using the synchronous dynamic random access memory (SDRAM), then needed clock rate reduces from 81.774004 MHz to 46.660047 MHz at the 8× speed and from 163.54801 MHz to 93.320093 MHz at the 16× speed.

In fact, the disclosed method and system also reduce the transmitting data rate and the cycles of the SDRAM. It is thus seen that the invention is more efficient in decoding than the prior art.

Certain variations would be apparent to those skilled in the art, which variations are considered within the spirit and scope of the claimed invention.

What is claimed is:

1. A data decoding method for decoding data which is obtained by adding two series of error correction code to a scrambled data added with error detection code, the method comprising the steps of:
reading in the modulated data from the recording medium for demodulation and storing the demodulated data to a memory module, using the demodulated data to perform a first-time first series of error correction code decoding to generate error positions and error magnitudes of the first-time first series of error correction code decoding for executing error corrections on the demodulated data in the memory module, and using a first descrambling module to descramble the demodulated data to generate descrambled data; and
using the error positions and error magnitudes of the first-time first series of error correction code decoding and the descrambled data to compute an EDC result and, when no error is found in the main data, allowing the access of the main data in the memory module and, when errors is found in the main data, continuing the following steps of:
using a second decoding module to read the demodulated data from the memory module and performing a first-time second series of error correction code decoding to generate error positions and error magnitudes of the first time second series of error correction code decoding for executing error corrections on the demodulated data; and
using the error positions and error magnitudes of the first time second series of error correction code decoding to combine with the previously computed EDC result to re-compute the EDC result and allowing the access of the main data in the memory module when no error is found in the main data;
wherein when errors is found in the main data, the second decoding module keeps reading the demodulated data from the memory module and re-generates the error positions and error magnitudes of the first series or the second series of error correction code decoding in an alternative way, executes the error correction of the demodulated data, and uses the error positions and error magnitudes of the first series or the second series of error correction code decoding to combine with the previously computed EDC result to re-compute the EDC result.

2. The method of claim 1, wherein when no error is found in the main data, the step of allowing the access of the main data in the memory module is performed and further includes the step of reading the demodulated data from the memory module and using a second descrambling module to descramble the demodulated data to generate the main data.

3. The method of claim 1, wherein the procedure may be ended by setting a number of total EDC computations.

4. A data decoding system for decoding data which is obtained by adding two series of error correction code to a scrambled data added with error detection code, the system comprising:
a demodulating module, which reads the modulated data from the recording medium for demodulation and generates demodulated data;
a memory module, which stores the demodulated data processed by the demodulating module;
a first descrambling module, which receives the demodulated data from the demodulating module for descrambling to generate descrambled data;
a first decoding module, which receives the demodulated data from the demodulating module to perform a first-time first series of error correction code decoding to generate error positions and error magnitudes of the first-time first series of error correction code decoding;
a second decoding module, which reads the demodulated data from the memory module to perform a first-time second series of error correction code decoding to generate error positions and error magnitudes of the first-time second series of error correction code decoding;
an EDC computation module, which receives the descrambled data and error positions and error magnitudes of the first-time first series of error correction code decoding to compute an EDC result or combines the error positions and error magnitudes of the first-time second series of error correction code decoding and the previously computed EDC result to re-compute the EDC result; and
an error correction module, which uses the error positions and error magnitudes of the first time first series of error correction code decoding or the first-time second series of error correction code decoding to correct errors of the demodulated data in the memory module;
wherein, when no error is found in the main data, the EDC computation module allows access of the main data stored in the memory module and, when errors is found in the main data, the second decoding module keeps reading the demodulated data from the memory module and re-generates the error positions and error magnitudes of the first series of error correction code decoding or the second series of error correction code decoding in an alternative way, to correct errors of the demodulated data in the memory module by the error correction module and to combine with the previously computed EDC result for re-computing the EDC result by the EDC computation module.

5. The system of claim 4 further comprising a second descrambling module, wherein when no error is found in the main data, it reads the demodulated data from the memory module and descrambles the demodulated data to generate the main data.

6. The system of claim 4, wherein the procedure may be ended by setting a number of total EDC computations.

7. A data decoding method for decoding data which is obtained by adding two series of error correction code to a scrambled data added with error detection code, the method comprising the steps of reading the modulated data from the recording medium, generating demodulated data by demodulation and storing them in a memory module, performing a first series of error correction code decoding and a second series of error correction code decoding, correcting errors of the demodulated data in the memory module, and providing the main data in the memory when no error is found in the main data after EDC computation, which is characterized in that the data stored in the memory module are scrambled main data, which are descrambled after the user requests for the main data.

8. A data decoding system for decoding data which is obtained by adding two series of error correction code to a scrambled data added with error detection code, the system comprising a demodulating module, which reads the modulated data from the recording medium for demodulation and generates demodulated data, a memory module, which stores the demodulated data processed by the demodulating module, a first descrambling module, which receives the demodulated data from the demodulating module for descrambling to generate descrambled data, a first decoding module and a second decoding module, which perform a first series of error correction code decoding and a second series of error correction code decoding, an error correction module, which corrects errors in the demodulated data in the memory module, and an EDC computation module, which detects if there is any error in the main data after EDC computation, the EDC computation module also allowing the access of the main data in the memory module when no error is found in the main data after the EDC computation, which is characterized in that the data stored in the memory module are scrambled main data, which are descrambled after the user requests for the main data.
